(19) United States
(12) Patent Application Publication
(10) Pub. No.: US 2017/0323902 A1
(43) Pub. Date: Nov. 9, 2017

(54) METHOD, APPARATUS, AND SYSTEM FOR IMPROVED CELL DESIGN HAVING UNIDIRECTIONAL METAL LAYOUT ARCHITECTURE

(71) Applicant: GLOBALFOUNDRIES INC., Grand Cayman (KY)

(72) Inventors: Jia Zeng, Sunnyvale, CA (US); Lei Yuan, Cupertino, CA (US); Jongwook Kye, Pleasonton, CA (US); Harry J. Levinson, Saratoga, CA (US)

(73) Assignee: GLOBALFOUNDRIES INC., Grand Cayman (KY)

(21) Appl. No.: 15/149,066

(22) Filed: May 6, 2016

(51) Int. Cl. H01L 27/118; H01L 27/092; H01L 23/528; H01L 21/3205; H01L 23/522; H01L 21/768; H01L 27/105; H01L 27/02

(52) U.S. Cl. CPC H01L 27/11807; H01L 27/105; H01L 27/092; H01L 27/0207; H01L 21/32053; H01L 23/5226; H01L 21/76877; H01L 23/528

(57) ABSTRACT

At least one method, apparatus and system disclosed involves circuit layout for comprising a unidirectional metal layout. A first trench silicide (TS) formation is formed in a first active area of a functional cell. A first CA formation if formed above the first TS formation. A first vertical metal formation is formed in a first metal layer from the first active area to a second active area of the functional cell. The first vertical metal formation is formed offset relative to, and in contact with, the CA formation. A second TS formation is formed in a second active area of the functional cell. A second CA formation is formed above the second TS formation. The CA formation is formed offset the first vertical metal formation, operatively coupling the first and second active areas.

### BACKGROUND OF THE INVENTION

### Field of the Invention

Generally, the present disclosure relates to the manufacture of sophisticated semiconductor devices, and, more specifically, to various methods and structures, including unidirectional metal layout, for using improved cell routability for metal lines for manufacturing integrated circuits.

### Description of the Related Art

The technology explosion in the manufacturing industry has resulted in many new and innovative manufacturing processes. Today's manufacturing processes, particularly semiconductor manufacturing processes, call for a large number of important steps. These process steps are usually vital, and therefore, require a number of inputs that are generally fine-tuned to maintain proper manufacturing control.

The manufacture of semiconductor devices requires a number of discrete process steps to create a packaged semiconductor device from raw semiconductor material. The various processes, from the initial growth of the semiconductor material, the slicing of the semiconductor crystal into individual wafers, the fabrication stages (etching, doping, ion implanting, or the like), to the packaging and final testing of the completed device, are so different from one another and specialized that the processes may be performed in different manufacturing locations that contain different control schemes.

Generally, a set of processing steps is performed on a group of semiconductor wafers, sometimes referred to as a lot, using semiconductor-manufacturing tools, such as exposure tool or a stepper. As an example, an etch process may be performed on the semiconductor wafers to shape objects on the semiconductor wafer, such as polysilicon lines, each of which may function as a gate electrode for a transistor. As another example, a plurality of metal lines, e.g., aluminum or copper, may be formed that serve as conductive lines that connect one conductive region on the semiconductor wafer to another.

In this manner, integrated circuit chips may be fabricated. In some cases, integrated circuit or chips may comprise various devices that work together based upon a hard-coded program. For example, application-specific integrated circuit (ASIC) chips may use a hard-coded program for various operations, e.g., boot up and configuration processes. The program code, in the form of binary data, is hard-coded into the integrated circuit chips.

When designing a layout of various devices with an integrated circuits (e.g., CMOS logic architecture), designers often select pre-designed functional cells comprising various features (e.g., diffusion regions, transistors, metal lines, vias, etc.) and place them strategically to provide an active area of an integrated circuit. One challenge of designing a layout is accommodating ever-increasing density of cell components and still maintain routability for connecting various components of the cells. This is increasingly a challenge as dimensions of these components get smaller, such as for 10 nm or lower integrated circuit designs.

In order to accommodate smaller integrated circuit designs, designers have provided more dense, smaller-track functional cells (e.g., 10-track or lower functional cells). For larger track designs, generally, designers desire to have a unidirectional metal-1 (M1) design where M1 is parallel to the gate (PC) structures, while allocating metal-2 (M2) as power rail. However, with smaller-track designs, in order to complete routing, designers are forced to make M1 bi-directional.

Because of the power rail limit in a cell, there is a desire to make M0/M1 horizontal-directional metal structures in circuits of smaller track dimensions. That is, since the power rail runs horizontal, it is desirable that M1 also runs horizontal. However, in order to make M1 unidirectional for smaller-designs (e.g., 10-track or smaller), designers are forced to use other resources, such as CA/TS pass-through structures. FIG. 1 illustrates a stylized depiction of a typical functional cell having a local interconnect formation/trench silicide, CA/TS pass-through structure.

FIG. 1 illustrates a stylized depiction of a cell 100 that comprises a plurality of PC (gate) formations 110. An intermediate, local interconnect formation CB metal formation 150 may be used to connect up some gates 310 to formations in other/upper metal layer. The CB formation 150 is slightly offset on the gate formation 110. The cell 100 includes a 1^{st} active region 120 and a 2^{nd} active region 130. The cell 100 may also comprise local interconnect formations, i.e., a 1^{st} CA formation 360 and a 2^{nd} CA formation 365. The 1^{st} CA formation 360 may be connected to the active region 120 using a via 361, and the 2^{nd} CA formation 365 may be connected to the active region 330 using a via 366. The 1^{st} CA formation 360 from the NMOS region may be connected to the 2^{nd} CA formation 365 by using a middle-of-line (MOL) structure, i.e., a CA/TS pass-through 140.

Despite the offset of the CB formation 150 away from the CA/TS pass-through 140, the CB to CA/TS pass-through is sufficiently close such that it could cause shorts between the CB formation 150 and the CA/TS pass-through 140. Further, the diffusion area between the CB to CA/TS pass-through can become too small.

The CA/TS pass-through 140 can be problematic during processing of a semiconductor device. For example, the usage of a CA/TS pass-through 140 causes a reduction of useful active regions in the cell. The active regions (i.e., the 1^{st} and 2^{nd} active regions 120, 130) may be pushed to the sides and/or may be limited in the size of the active regions in order to allow for the CA/TS pass-through 140 connections. As the contacted poly pitch (CPP) of cells decrease, the space issues caused by the CA/TS pass-through 140 are exacerbated.

FIGS. 2 and 3 describe the spacing issues caused by use of CA/TS pass-through 140 in cell with decreased CPPs. FIGS. 2 and 3 illustrate stylized depictions of cross sectional views of the CA/TS pass-through of FIG. 1 (see cut-line 150). FIG. 2 illustrates a stylized depiction of a cross-sectional view of the cell 100 of FIG. 1 with a CPP of 90 nm. Generally, the CB formation 150 the gate formations 110 to metal layers, while the CA/TS pass-through 140 connects the source/drain associated with the gates 110 to metal layers. As shown in FIG. 2, the CB formation 150 is offset from the gate (PC) structure 110 by about 19 nm. The center of the gate structure 110 is about 45 nm from the CA/TS pass-through 140 center. The center of the CB formation 150 is about 64 nm from the center of the CA/TS pass-through 140.

In contrast to the example of FIG. 2, where the CPP is 90 nm, as the CPP for cells decrease, problems with the state of the art designs increase. FIG. 3 illustrates a stylized depiction of a cross-sectional view of the cell 100 of FIG. 1 with a CPP of 64 nm. In this case, the CB formation 150 is offset from the gate (PC) structure 110 by about 8 nm. The center of the gate structure 110 is only about 32 nm from the CA/TS pass-through 140 center. The center of the CB formation 150 is only about 40 nm from the center of the CA/TS pass-through 140. This causes the CB to CA/TS pass-through to be sufficiently small to cause problems. As noted, even with the offset of the CB formation 150 away from the CA/TS pass-through 140, the CB to CA/TS pass-through is close enough to cause shorts between the CB formation 150 and the CA/TS pass-through 140 as a result of slight process variations.

Therefore, as CPP of cells become smaller and denser, the likelihood of process errors increases. Accordingly, as described above, using CA/TS pass-through 140 force designers to shrink active areas and/or move active areas around in an undesirable fashion. This can cause device performance problems. The usage of CA/TS pass-through causes difficulties in shrinking integrated circuit devices, in improving performance, and in maintaining sufficient active areas when decreasing track sizes.

Designers have attempted at least three basic design approaches to avoid using CA/TS pass-through 140, as shown in FIGS. 4-6. FIG. 4 illustrates a stylized depiction of a typical MO-less architecture. FIG. 4 illustrates a cell 400 that comprises a plurality of gates structures 410. A CB formation 450 may be used to connect gates 410 to formations in other/upper metal layer (i.e., M1 layer). The cell 400 includes a 1^{st} active region 420 (e.g., NMOS region) and a 2^{nd} active region 430 (e.g., PMOS region). The cell 400 comprises a 1^{st} metal formation 492 formed over the 1^{st} active region 420. The cell 400 also comprises a 2^{nd} metal formation 494 formed over the 2^{nd} active region 430. The 1^{st} and 2^{nd} metal formations 492, 494 are formed in a horizontal configuration, and may be used as power rails. A 3^{rd} metal formation 496 is formed in a vertical configuration. The CB formation 450 connects a gate 410 to the 3^{rd} M1 formation 496.

The cell 400 may also comprise a 1^{st} CA formation 460 and a 2^{nd} CA formation 465. The 1^{st} CA formation 460 may be formed in the 1^{st} active region 420, and the 2^{nd} CA formation 465 may be formed in the 2^{nd} active region 430. The 1^{st} active region 420 may be connected to the 2^{nd} active region 430 by using a “C” shaped M1 structure 490. The M1 structure 490 is connected to the 1^{st} active region 420 using a via 461, while the M1 structure 490 is also connected to the 2^{nd} active region 430 using a via 466.

The C-shaped M1 arrangement of the cell 400 causes “wrong-way” M1 features wherein M1 features have to be used in undesirable directions for routing, thereby causing the M1 metal layer to be bi-directional. This is problematic in performing side-wall patterning since this process requires unidirectional metal layer structures. Wrong-way power rail architecture requires triple patterning M1 LELELE. This process can cause printability and manufacturing problems.

The C-shaped structures may cause various other process issues. For example, usage of the C-shaped structures requires more space, and thus, causes the cell 400 to become taller. This causes the integrated circuit formed using the cell 400 to be larger, and increases power consumption. Further, formation of the C-shaped structures can cause lateral connection problems. Also, more silicon would be required at the corners of the C-shaped structures, which could cause process errors. Further, the C-shaped structures cause various routing congestion problems.

Designers also have used other approaches to avoid using CA/TS pass-through 140, as shown in FIG. 5. FIG. 5 illustrates a stylized depiction of a typical M0 architecture. FIG. 5 shows a cell 500 that comprises a plurality of gates structures 510. A CB formation 550 may be used to connect gate 510 to formations in other/upper metal layer (i.e., M0, M1 layers). The cell 500 includes a 1^{st} active region 520 (e.g., NMOS region) and a 2^{nd} active region 530 (e.g., PMOS region). The cell 500 comprises a 1^{st} M1 formation 592 formed over the 1^{st} active region 520. The cell 500 also comprises a 2^{nd} M1 formation 594 formed over the 2^{nd} active region 530. The 1^{st} and 2^{nd} M1 features 592, 594 are formed in a horizontal manner. The 1^{st} and 2^{nd} metal formations 592, 594 are formed in a horizontal configuration, and may be used as power rails. A 3^{rd} metal formation 596 is formed in a vertical configuration. The CB formation 550 connects a gate 510 to the 3^{rd} M1 formation 596. Further, a plurality of TS structures 542 are formed in the active areas.

The cell 500 comprises a 1^{st} M0 structure 583 in the 1^{st} action region 520, and a 2^{nd} M0 structure 585 in the 2^{nd} active region 530. The 1^{st} and 2^{nd} M0 structures 583, 585 are formed in a horizontal configuration and is generally connected to power/ground nodes, using 1^{st} and 2^{nd} vias 567, 568, respectively.

The cell 500 may also comprise local interconnect formations, i.e., a 1^{st} CA formation 560 and a 2^{nd} CA formation 565. The 1^{st} CA formation 560 may be connected to 3^{rd} M0 structure 587, and the 2^{nd} CA formation 565 may be connected to the 4^{th} M0 structure 589. The 3^{rd} and 4^{th} M0 structures 587, 589 are also formed in a horizontal configuration.

The 1^{st} active region 520 may be connected to the 2^{nd} active region 530 by using M1 structure 570 and 3^{rd} and 4^{th} vias 591, 592, respectively. As shown in FIG. 5, the M0 features are horizontal, and the M1 features are vertical, except for the power rail M1 formations, which are horizontal. Again, this also causes wrong-way M1 features, wherein M1 features have to be used in undesirable directions for routing, thereby causing the M1 metal layer to be bi-directional. Again, this is problematic in performing side-wall patterning, as described above.

FIG. 6 illustrates a stylized depiction of a typical CB-M0 handshake architecture. FIG. 6 shows a cell 600 that comprises a plurality of gates structures 610. A local interconnect formation, i.e., CB formation 550, is used for a CD-M0 horizontal handshake formation. The cell 600 includes a 1^{st} active region 620 (e.g., NMOS region) and a 2^{nd} active region 630 (e.g., PMOS region). The cell 600 comprises a 1^{st} M1 formation 692 formed over the 1^{st} active region 620. The cell 600 also comprises a 2^{nd} M1 formation 694 formed over the 2^{nd} active region 630. The 1^{st} and 2^{nd} M1 features are formed in a horizontal manner.

The cell 600 comprises a 1^{st} M0 structure 683 in the 1^{st} action region 620 and a 2^{nd} M0 structure 685 in the 2^{nd} active region 530. The M0 structures 683, 685 are formed in a horizontal configuration and is generally connected to power/ground nodes, using 1^{st} and 2^{nd} vias 667, 668, respectively. The cell 600 comprises a 3^{rd} M0 structure 587 that is coupled to a CB structure 650, which is electrically coupled to the 3^{rd} M0 structure 683. The 3^{rd} M0 structure 687 is electrically coupled to the to the 3^{rd} M1 structure 687 using a 5^{th} via 687, wherein the 3^{rd} M0 687, the CB structure 650, and the 5^{th} via 693 form a CB-M0 horizontal handshake configuration. The 3^{rd} M0 structure 687 is formed in a horizontal configuration.

The 1^{st} active region 520 may be connected to the 2^{nd} active region 530 by using the 4^{th} M1 structure 690 and 3^{rd} and 4^{th} vias 691, 692, respectively. As shown in FIG. 6, the M0 features are formed in a horizontal configuration, and the M1 features are vertical, except for the horizontal power rail M1 formations. The configuration of the cell 600 causes wrong-way M1 features, wherein M1 features have to be used in undesirable directions for routing, thereby causing the M1 metal layer to be bi-directional. As described above, issues relating to bi-directional metal formations can be problematic in performing side-wall patterning. Accordingly, as described above, there are various inefficiencies, errors, and other problems associated with the state-of-art.

The present disclosure may address and/or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods, apparatus and system for providing a circuit layout comprising unidirectional metal layout. A first trench silicide (TS) formation is formed in a first active area of a functional cell. A first CA formation if formed above the first TS formation. A first vertical metal formation is formed in a first metal layer from the first active area to a second active area of the functional cell. The first vertical metal formation is formed offset relative to, and in contact with, the CA formation. A second TS formation is formed in a second active area of the functional cell. A second CA formation is formed above the second TS formation. The CA formation is formed offset the first vertical metal formation, operatively coupling the first and second active areas.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a stylized depiction of a cell that comprises a plurality of gate formations;

FIG. 2 illustrates a stylized depiction of a cross-sectional view of the cell of FIG. 1 with a CPP of 90 nm;

FIG. 3 illustrates a stylized depiction of a cross-sectional view of the cell of FIG. 1 with a CPP of 64 nm;

FIG. 4 illustrates a stylized depiction of a typical MO-less architecture;

FIG. 5 illustrates a stylized depiction of a typical MO architecture;

FIG. 6 illustrates a stylized depiction of a typical CB-M0 hand-shake architecture;

FIG. 7 illustrates a stylized depiction of a functional cell having an CA-M0 and CB-M0 offset side-touch handshake, in accordance with embodiments herein;

FIG. 8 illustrates a stylized depiction of a cross-sectional view of a first portion of the cell 700 of FIG. 7, in accordance with embodiment herein;

FIG. 9 illustrates a stylized depiction of a cross-sectional view of a second portion of the cell 700 of FIG. 7, in accordance with embodiment herein;

FIG. 10 illustrates a stylized depiction of a cell comprising horizontal M1 and vertical M0 formation and having CA-M0 and CB-M0 offset side-touch handshakes, in accordance with embodiments herein;

FIG. 11 illustrates a stylized depiction of a NAND function cell, in accordance with embodiments herein; and

FIG. 12 illustrates semiconductor device processing system for performing a design process, in accordance with some embodiments herein.

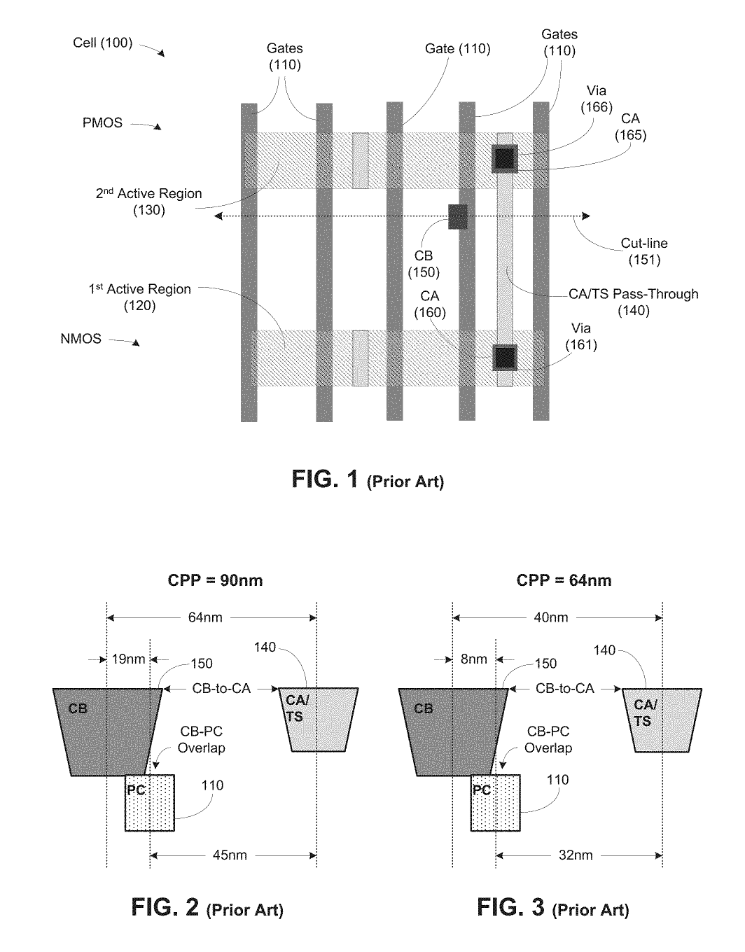

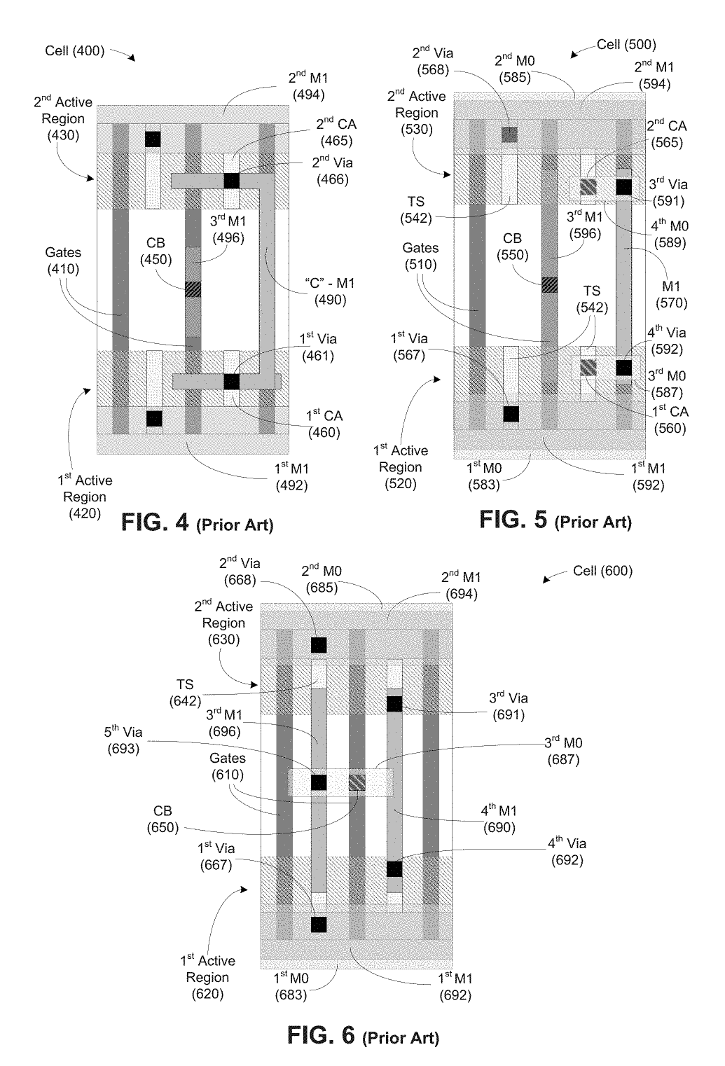

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for using middle-of-line (MOL) structures, such as local interconnect formations CA, CB, and trench silicide (TS) formations to provide connections/routing to enable use of unidirectional metal formations. Embodiments herein provide for a cell for an integrated circuit that comprises a CA-M0 and CB-M0 offset side-touch hand-shake design. Embodiments herein provide for source/drain connections that comprise unidirectional metal connections. Embodiments herein also provide for an increased amount of edge placement tolerance as compared to CA/TS pass-through designs.

Further, embodiments herein provide for a middle of line (MOL) architecture that substantially reduces or eliminates “wrong way” power rails, i.e., substantially reducing or eliminating metal structures on a metal layer that run in a different direction as compared to power rail structures of that metal layer. Embodiments herein provide for unidirectional M1 (e.g., horizontal unidirectional) SADP compatible designs. Using embodiments herein, improved scalability may be achieved as compared to wrong-way M1 architecture. Designs provided by embodiments herein provide for all MOL layers of an integrated circuit to be ultra-regular and compatible with LELE and SADP designs.

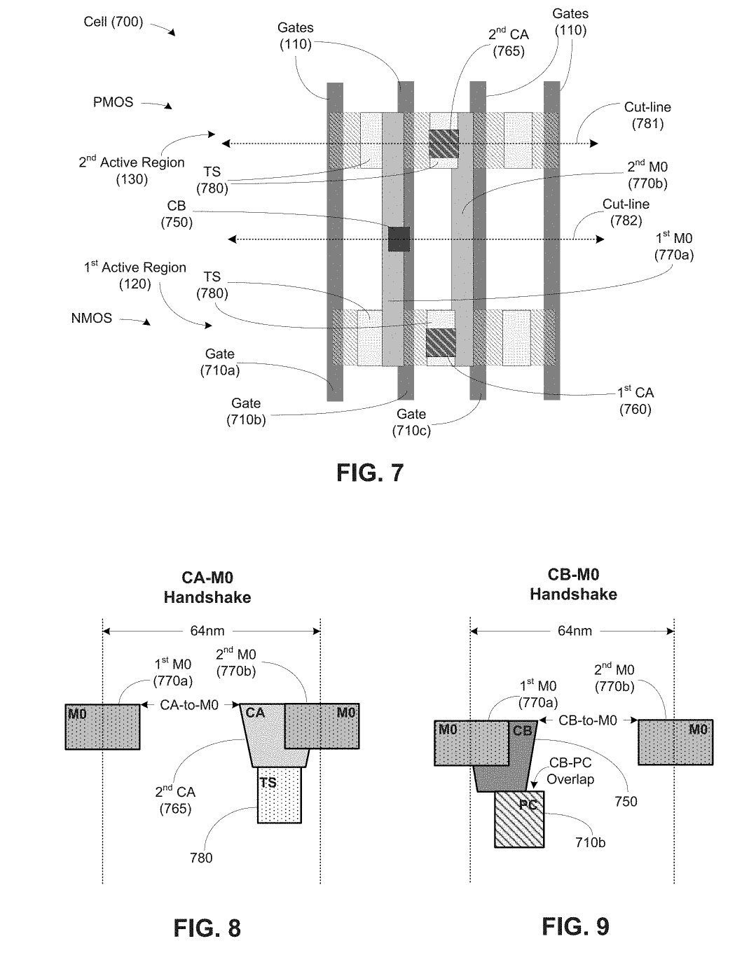

Turning now to FIG. 7, a stylized depiction of a functional cell having a CA-M0 and CB-M0 offset side-touch handshake, in accordance with embodiments herein is illustrated. FIG. 7 shows a cell 700 that comprises a plurality of PC (gate) formations 710a, 710b, 710c. A local interconnect CB formation 750 may be used to connect the gate 710b to formations in other/upper metal layers. The CB formation 750 is offset relative to the gate formation 710b. Further, a 1^{st} M0 metal formation 770a is formed in a vertical configuration. The 1^{st} M0 formation 770a is offset relative to the CB formation 750 and the gate 710b.

The cell 700 includes a 1^{st} active region 720 (e.g., NMOS region) and a 2^{nd} active region 730 (e.g., PMOS region). Trench silicide (TS) formations 780 may be formed in the 1^{st} and 2^{nd} active areas 720, 730. A 2^{nd} M0 formation 770b is formed in a vertical configuration. The 2^{nd} M0 formation 770b is formed in an offset fashion relative to the gate 710c. The cell 700 may also comprise local interconnect formations, a 1^{st} CA formation 760 in the 1^{st} active region 720, and a 2^{nd} CA formation 765 in the 2^{nd} active region. The 1^{st} and 2^{nd} CA formations 760, 765 are formed offset relative to the 2^{nd} M0 formation 770b and aligned on a TS formation 780, as shown. In this manner, the 1^{st} and 2^{nd} active regions 720, 730 may be operatively coupled using vertical M0 features.

Turning now to FIG. 8, a stylized depiction of a cross-sectional view of a first portion of the cell 700 of FIG. 7, in accordance with embodiment herein, is illustrated. Referring simultaneously to FIGS. 7 and 8, a cross-sectional view of the cell 700 at the cut line 781 (FIG. 7) is shown.

As shown in FIG. 8, the 2^{nd} CA formation 765 is formed offset to the 2^{nd} M0 formation 770b. The 2^{nd} CA 765 formation is formed above the TS formation 780, within the 2^{nd} active area 730. The centers of the 1^{st} M0 formation 770a and the 2^{nd} M0 formation 770b are separated by a single track spacing, e.g., 64 nm. The CA-M0 handshake illustrated in FIG. 8 may be used to replace a TS pass-through to operatively couple the 1^{st} and 2^{nd} active areas 720, 730.

Turning now to FIG. 9, a stylized depiction of a cross-sectional view of a second portion of the cell 700 of FIG. 7, in accordance with embodiment herein, is illustrated. Referring simultaneously to FIGS. 7 and 9, a cross-sectional view of the cell 700 at the cut line 782 (FIG. 7) is shown.

As shown in FIG. 9, the CB formation 750 is formed offset relative to the gate structure 710b, leaving a CB-PC overlap. The 1^{st} M0 formation 770a is formed offset relative to the CB 750. The 2^{nd} M0 formation 770b is formed offset to the gate formation 710c. The centers of the 1^{st} M0 formation 770a and the 2^{nd} M0 formation 770b are separated by a single track spacing, e.g., 64 nm. The CB-M0 handshake illustrated in FIG. 9 provides for enabling gate pick-up, using the CB formation 750.

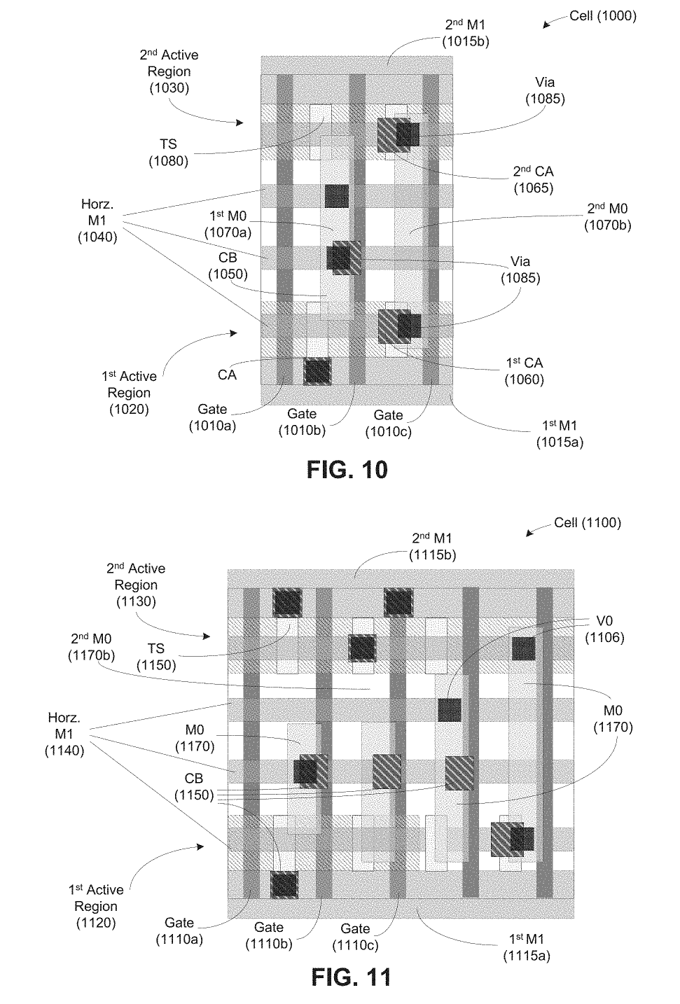

The offset nature of the CA-M0 and CB-M0 handshaking exemplified in FIGS. 7-10, provide for forming all of the M0 formations in a vertical configuration. Therefore, all M1 metal formations may then be formed in horizontal configurations, as described in FIG. 10 and accompanying description below. Since M0 formations are on the same level as CB formations, they can be formed at the same height, thereby increasing process tolerances. Since M0 formations are shifted, and since there is no pass-through, an increase in the tolerance margin is realized because of the position of CB and the vertical routing provided by this design. The problems associated with the CA/TS pass-through design are substantially decreased or eliminated.

Turning now to FIG. 10, a stylized depiction of a cell comprising horizontal M1 and vertical M0 formations, and having CA-M0 and CB-M0 offset side-touch handshakes, in accordance with embodiments herein, is illustrated. FIG. 10 shows a cell 1000 that comprises a plurality of PC (gate) formations 1010a, 1010b, 1010c. A CB formation 1050 may be used to connect the gate 1010b to formations in other/upper metal layers. The CB formation 1050 is offset relative to the gate formation 1010b. Further, a 1^{st} M0 metal formation 1070a is formed in a vertical configuration. The 1^{st} M0 formation 1070a is offset relative to the CB formation 1050 and the gate 1010b. Vias 1085 may be used to operatively couple the metal formations (M1 and M0 formations) to MOL features, such as CA 1060, 1065 and CB 1050 features.

The cell 1000 includes a 1^{st} active region 1020 (e.g., NMOS region) and a 2^{nd} active region 1030 (e.g., PMOS region). TS formations 1080 may be formed in the 1^{st} and 2^{nd} active areas 1020, 1030. Further, a 1^{st} M1 horizontal power rail 1015a is formed in the 1^{st} active area 1020. A 2^{nd} M1 horizontal power rail 1015b is formed in the 2^{nd} active area 1030. Also, a plurality of M1 formations 1040 in a horizontal configuration may be formed in the cell 1000. Therefore, all of the M1 formations, including the M1 power rails, are formed in a unidirectional, horizontal configuration.

A plurality of additional M0 formations may be formed in a unidirectional, vertical configuration. For example, a 2^{nd} M0 formation 1070b is formed in a vertical configuration. The 2^{nd} M0 formation 1070b is formed in an offset manner (side-touch) relative to the gate 1010c. The cell 1000 may also comprise a 1^{st} CA formation 1060 in the 1^{st} active region 1020, and a 2^{nd} CA formation 1065 in the 2^{nd} active region 1030. The 1^{st} and 2^{nd} CA formations 1060, 1065 are formed offset (side-touch) to the 2^{nd} M0 formation 1070b and to a TS formation 1080. In this manner, the 1^{st} and 2^{nd} active regions 1020, 1030 may be operatively coupled using vertical M0 features.

Using the vertical, unidirectional M0 formations, along with horizontal, unidirectional M1 formations described above, various connections (e.g., source/drain connections) may be made in an integrated circuit without bending metal formations. This may provide increased edge placement tolerance, which provides routing and space efficiencies. Using the CA-M0 and CB-M0 offset side-touch handshake designs described herein, MOL architecture that substantially eliminates wrong-way power rails, may be achieved. Further, designs provided by embodiments herein provide for increased scalability and more efficient self-aligned double patterning and lithography-etch-lithography-etch (LELE) processing.

Using the CA-M0/CB-M0 offset side-touch handshake provided by embodiments herein, more complex functional cells may be provided For example, using components such as the components described in FIG. 10, complex cells such as an AND cell, an OR cell, a NAND cell, a NOR cell, an XOR cell, an inverter cell, an AND-OR-INVERT (AOI) cell, (e.g., AOI22×1), a memory portion cell, and/or a cell that performs another circuit function, etc. may be formed.

Turning now to FIG. 11, a stylized depiction of a NAND function cell, in accordance with embodiments herein, is illustrated. FIG. 11 shows a NAND function cell 1100 that comprises a plurality of PC (gate) formations 1011. A plurality of CB formations 1150 may be used to connect several gates 1110 to formations in other/upper metal layers. The CB formations 1150 are offset from the gate formations 1110. Further, a plurality of M0 metal formations 1170 are formed in vertical configurations. The M0 formations 1170 are offset relative to the CB formations 1150 and the gates 1110.

The cell 1100 includes a 1^{st} active region 1120 (e.g., NMOS region) and a 2^{nd} active region 1130 (e.g., PMOS region). TS formations 1080 may be formed in the 1^{st} and 2^{nd} active areas 1120, 1130. Further, a 1^{st} M1 horizontal power rail 1115a is formed in the 1^{st} active area 1120. A 2^{nd} M1 horizontal power rail 1115b is formed in the 2^{nd} active area 1130. Further a plurality of M1 formations 1140 in horizontal configurations are formed in the cell 1100. Therefore, all of the M1 formations, including the M1 power rails, are formed in a unidirectional, horizontal configuration. A plurality of vias 1106 may be used to couple various formations to metal layer, e.g., M1 formations 1140, to MOL features (CB, CA, TS features).

The cell 1100 may also comprise a CA formation 1160 in the 1^{st} active region 1120. The 1^{st} CA formation 1160 is formed offset to a M0 formation 1170 and to a TS formation 1180. In this manner, the 1^{st} and 2^{nd} active regions 1020, 1030 may be operatively coupled using vertical M0 features. The arrangement of the formations in the cell 1100 provides for a NAND gate. Similar formations, with modifications such increased number of gates 1110, more elongated CB formations 1150, etc., may be implemented to form other types of functional cells, such as AND-OR-Invert circuits, etc. Using the vertical, unidirectional M0 formations, along with horizontal, unidirectional M1 formations, and the CA-M0/CB-M0 handshakes described above, various efficient cell designs that are SADP and LELE process friendly may be formed.

Those skilled in the art would appreciate that even though some embodiments herein are described in terms of a cell, similar concepts would apply to embodiments where circuits described herein are formed on an integrated circuit without using standard cells.

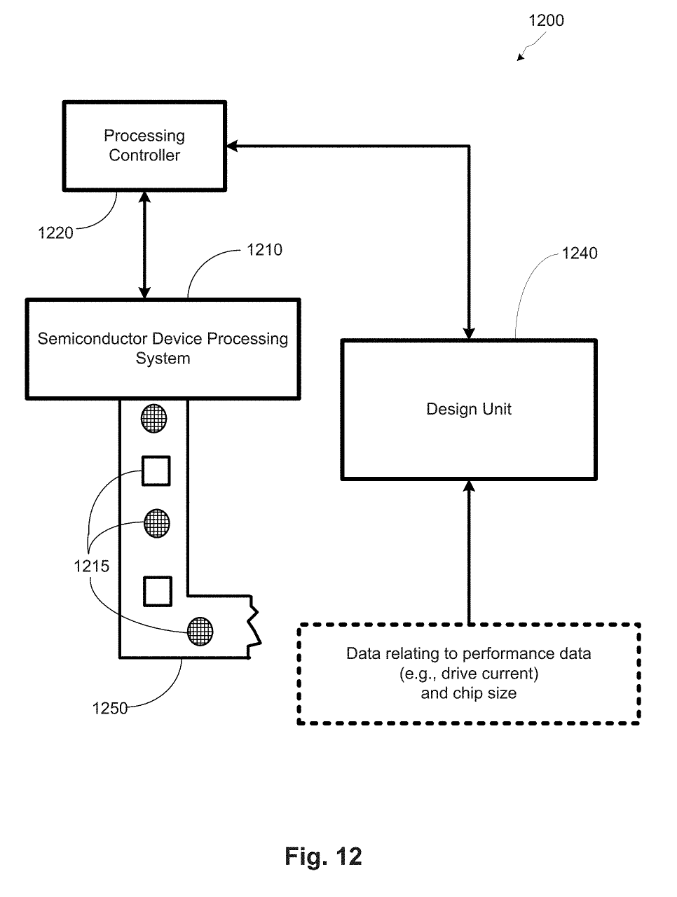

Turning now to FIG. 12, a stylized depiction of a system for fabricating a device comprising unidirectional metal features, in accordance with some embodiments herein, is illustrated. The semiconductor device processing system 1210 may comprise various processing stations, such as etch process stations, photolithography process stations, CMP process stations, etc. One or more of the processing steps performed by the processing system 1210 may be controlled by the processing controller 1220. The processing controller 1220 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device processing system 1210 may produce integrated circuits on a medium, such as silicon wafers. The production of integrated circuits by the device processing system 1210 may be based upon the circuit designs provided by the integrated circuits design unit 1240. The processing system 1210 may provide processed integrated circuits/devices 1215 on a transport mechanism 1250, such as a conveyor system. In some embodiments, the conveyor system may be sophisticated clean room transport systems that are capable of transporting semiconductor wafers. In one embodiment, the semiconductor device processing system 1210 may comprise a plurality of processing steps, e.g., the 1^{st} process step, the 2^{nd} process set, etc., as described above.

In some embodiments, the items labeled “1215” may represent individual wafers, and in other embodiments, the items 1215 may represent a group of semiconductor wafers, e.g., a “lot” of semiconductor wafers. The integrated circuit or device 1215 may be a transistor, a capacitor, a resistor, a memory cell, a processor, and/or the like. In one embodiment, the device 1215 is a transistor and the dielectric layer is a gate insulation layer for the transistor.

The integrated circuit design unit 1240 of the system 1200 is capable of providing a circuit design that may be manufactured by the semiconductor processing system 1210. The design unit 1240 may receive data relating to the functional cells to utilize, as well as the design specifications for the integrated circuits to be designed. In one embodiment, the integrated circuit design unit 1240 may provide cell designs that comprise horizontal M1 unidirectional formation, vertical M0 unidirectional formations, CA-M0 and CB-M0 offset, side-touch handshake formations.

In other embodiments, the integrated circuit design unit 1240 may perform an automated determination of the shifts, automatically select a substitute or child, and automatically incorporate the substitute cell into a design. For example, once a designer or a user of the integrated circuit design unit 1240 generates a design using a graphical user interface to communicate with the integrated circuit design unit 1240, the unit 1240 may perform automated modification of the design using substitute cells. In other embodiments, the integrated circuit design unit 1240 may be capable of automatically generating one or more cells that comprise horizontal M1 unidirectional formation, vertical M0 unidirectional formations, CA-M0 and CB-M0 offset, side-touch handshake formations, or retrieve one or more such cells from a library.

The system 1200 may be capable of performing analysis and manufacturing of various products involving various technologies. For example, the system 1200 may use design and production data for manufacturing devices of CMOS technology, Flash technology, BiCMOS technology, power devices, memory devices (e.g., DRAM devices), NAND memory devices, and/or various other semiconductor technologies.

The methods described above may be governed by instructions that are stored in a non-transitory computer readable storage medium and that are executed by, e.g., a processor in a computing device. Each of the operations described herein may correspond to instructions stored in a non-transitory computer memory or computer readable storage medium. In various embodiments, the non-transitory computer readable storage medium includes a magnetic or optical disk storage device, solid state storage devices such as flash memory, or other non-volatile memory device or devices. The computer readable instructions stored on the non-transitory computer readable storage medium may be in source code, assembly language code, object code, or other instruction format that is interpreted and/or executable by one or more processors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

1. A method, comprising:
forming a first trench silicide (TS) formation in a first active area of a functional cell;
forming a first local interconnect (CA) formation above said first TS formation;
forming a first vertical metal formation in a first metal layer from said first active area to a second active area of said functional cell, wherein said first vertical metal formation is formed in contact with said CA formation such that a portion of said CA formation underlies a portion of said first vertical metal formation;
forming a second TS formation in said second active area of said functional cell;
forming a second CA formation above said second TS formation, wherein said second CA formation is formed in contact with the first vertical metal formation such that a portion of said second CA formation underlies a portion of said first vertical metal formation, operatively coupling said first and second active areas.

2. The method of claim 1, further comprising:
forming a third local interconnect (CB) formation formed offset to, and in contact with, a first gate formation; and
forming a second vertical metal formation in said first metal layer offset relative to, and in contact with, said CB formation.

3. The method of claim 2, wherein said second vertical metal formation is formed partially offset to said first gate formation, and said first vertical metal formation is formed partially offset to a second gate formation.

4. The method of claim 2, further comprising:
forming a first horizontal metal formation formed in a second metal layer and in said first active area, wherein said first metal formation is coupled to said first CA formation and said first vertical metal formation by a first via; and
forming a second horizontal metal formation formed in a second metal layer and in said second active area, wherein said second metal formation is coupled to said second CA formation and said second vertical metal formation by a second via.

5. The method of claim 4, further comprising a third horizontal metal formation formed in said second metal layer, wherein said first metal formation is coupled to said CB formation and said second vertical metal formation by a third via.

6. The method of claim 5, further comprising:
forming a fourth horizontal metal formation formed in said second metal layer, wherein said third horizontal metal formation is configured as a first power rail; and
forming a fifth horizontal metal formation formed in said second metal layer, wherein said fourth horizontal metal formation is configured as a second power rail.

7. The method of claim 6, wherein
forming a first TS formation formed in said first active area, wherein said first TS formation is coupled to said fourth horizontal metal formation by a fourth via; and
forming a second TS formation formed in said second active area, wherein said second TS formation is coupled to said fifth horizontal metal formation by a fifth via.

8. The method of claim 7, further comprising forming a functional cell using at least said first and second vertical metal formations, said first, second, third, fourth, and fifth horizontal metal formation, said first and second CA formations, said first and second CB formations, said first and second TS formations, and said first, second, third, fourth, and fifth vias.

9. The method of claim 8, wherein forming a functional cell comprises forming at least one of a AND cell, an OR cell, a NAND cell, a NOR cell, and XOR cell, an inverter cell, an AND-OR-INVERT (AOI) cell, and a portion of a memory cell.

10. An integrated circuit, comprising:
a first trench silicide (TS) formation in a first active area;
a first local interconnect (CA) formation above said first TS formation;
a first vertical metal formation in a first metal layer spanning from said first active area to a second active area of said functional cell, wherein said first vertical metal formation is contact with said CA formation such that a portion of said CA formation underlies a portion of said first vertical metal formation;
a second TS formation in a second active area of said functional cell;
a second CA formation above said second TS formation, wherein said second CA formation is in contact with the first vertical metal formation such that a portion of said second CA formation underlies a portion of said first vertical metal formation, operatively coupling said first and second active areas.

11. The integrated circuit of claim 10, further comprising:
a third local interconnect (CB) formation formed offset to, and in contact with, a first gate formation; and
a second vertical metal formation in said first metal layer formed offset relative to, and in contact with, said CB formation.

12. The integrated circuit of claim 11, further comprising:
a first horizontal metal formation in a second metal layer and in said first active area, wherein said first metal formation is coupled to said first CA formation and said first vertical metal formation by a first via;
a second horizontal metal formation in a second metal layer and in said second active area, wherein said second metal formation is coupled to said second CA formation and said second vertical metal formation by a second via; and
a third horizontal metal formation formed in said second metal layer, wherein said first metal formation is coupled to said CB formation and said second vertical metal formation by a third via.

13. The integrated circuit of claim 12, further comprising:
a fourth horizontal metal formation formed in said second metal layer, wherein said third horizontal metal formation is configured as a first power rail; and
a fifth horizontal metal formation formed in said second metal layer, wherein said fourth horizontal metal formation is configured as a second power rail.

14. The integrated circuit of claim 13, further comprising:
a first TS formation formed in said first active area, wherein said first TS formation is coupled to said fourth horizontal metal formation by a fourth via; and
a second TS formation formed in said second active area, wherein said second TS formation is coupled to said fifth horizontal metal formation by a fifth via.

15. The integrated circuit of claim 10, wherein said integrated circuit is at least one of a AND cell, an OR cell, a NAND cell, a NOR cell, and XOR cell, an inverter cell, an AND-OR-INVERT (AOI) cell, and a portion of a memory cell.

16. A system, comprising:
a semiconductor device processing system for fabricating an integrated circuit device based upon a design comprising a functional cell; and
a processing controller operatively coupled to said semiconductor device processing system, said processing controller configured to control an operation of said semiconductor device processing system adapted to:
form a first trench silicide (TS) formation in a first active area of a functional cell;
form a first local interconnect (CA) formation above said first TS formation;
form a first vertical metal formation in a first metal layer from said first active area to a second active area of said functional cell, wherein said first vertical metal formation is formed in contact with said CA formation such that a portion of said CA formation underlies a portion of said first vertical metal formation;
form a second TS formation in a second active area of said functional cell; and
form a second CA formation above said second TS formation, wherein said CA formation is formed in contact with the first vertical metal formation such that a portion of said second CA formation underlies a portion of said first vertical metal formation, operatively coupling said first and second active areas.

17. The system of claim 16, further comprising a design unit adapted to receive a design for an integrated circuit device, wherein said design comprises a functional cell.

18. The system of claim 16, wherein said processing controller is further adapted to:
a first horizontal metal formation formed in a second metal layer and in said first active area, wherein said first metal formation is coupled to said first CA formation and said first vertical metal formation by a first via; and
a second horizontal metal formation formed in a second metal layer and in said second active area, wherein said second metal formation is coupled to said second CA formation and said second vertical metal formation by a second via;
a third horizontal metal formation formed in said second metal layer, wherein said first metal formation is coupled to a third local interconnect (CB) formation and said second vertical metal formation by a third via;
a fourth horizontal metal formation formed in said second metal layer, wherein said third horizontal metal formation is configured as a first power rail; and
a fifth horizontal metal formation formed in said second metal layer, wherein said fourth horizontal metal formation is configured as a second power rail.

19. The system of claim 18, further comprising:
a first TS formation formed in said first active area, wherein said first TS formation is coupled to said fourth horizontal metal formation by a fourth via; and
a second TS formation formed in said second active area, wherein said second TS formation is coupled to said fifth horizontal metal formation by a fifth via.

20. The system of claim 16, wherein said integrated circuit is at least one of a AND cell, an OR cell, a NAND cell, a NOR cell, and XOR cell, an inverter cell, an AND-OR-INVERT (AOI) cell, and a portion of a memory cell.
